(19) United States
(12) Patent Application Publication
(10) Pub. No.: US 2026/0090321 A1
(43) Pub. Date: Mar. 26, 2026

(54) SUBSTRATE PROCESSING APPARATUS, ARTICLE MANUFACTURING METHOD, SUBSTRATE PROCESSING METHOD, AND COMPUTER-READABLE RECORDING MEDIUM STORING PROGRAM TO PERFORM SUBSTRATE PROCESSING METHOD

(71) Applicant: CANON KABUSHIKI KAISHA, Tokyo (JP)

(72) Inventors: YUUJI EMA, Tochigi (JP); HIRO NORIKANE, Tochigi (JP)

(21) Appl. No.: 19/316,497

(22) Filed: Sep. 2, 2025

(30) Foreign Application Priority Data
Sep. 26, 2024 (JP) 2024-167514

(51) Int. Cl. H01L 21/67; H01L 21/677

(52) U.S. Cl. CPC H10P 72/0602; H10P 72/33

(57) ABSTRACT

One or more substrate processing apparatuses, one or more methods of manufacturing article(s), one or more substrate processing methods, and one or more computer-readable storage or recording mediums are provided herein. Provided is one or more embodiments of a substrate processing apparatus including a stage on which a substrate is mounted, a conveyor that operates to convey the substrate from the stage, a measuring sensor that operates to measure a temperature of the conveyor, an adjuster that operates to adjust a temperature of the substrate mounted on the stage, and a controller or processor that operates to perform an adjusting step of causing the adjuster to adjust the temperature of the substrate mounted on the stage so as to become the temperature of the conveyor measured by the measuring sensor.

### BACKGROUND

### Field of the Technology

The present disclosure is related to one or more embodiments of a substrate processing apparatus, one or more embodiments of an article manufacturing method, one or more embodiments of a substrate processing method, and one or more embodiments of a computer-readable recording medium storing a program for performing a substrate processing method.

### Description of the Related Art

Conventionally, when temperature unevenness occurs in a substrate surface of a substrate in a substrate processing apparatus, expansion or contraction locally occurs in the substrate, thereby changing an arrangement or shapes of shot regions in the substrate surface.

In the substrate processing apparatus, an actuator driven in a substrate conveying unit for conveying the substrate generates heat, and the heat is transferred to a substrate holding unit of the substrate conveying unit for holding the substrate and thus to the held substrate, thereby causing temperature unevenness in the substrate surface of the substrate.

Japanese Patent Laid-Open No. 2021-174858 discloses a substrate processing apparatus which suppresses occurrence of temperature unevenness in a substrate surface of a substrate by adjusting a temperature of a region of the substrate which is in contact with a substrate holding unit so as to be lower than a temperature of a region of the substrate which is not in contact with the substrate holding unit.

On the other hand, in recent years, the heat generation in a driven actuator is also increased along with an increase in speed and acceleration when the substrate is conveyed in a substrate conveying unit in a case where a throughput in a substrate processing apparatus is improved.

In the substrate processing apparatus disclosed in Japanese Patent Laid-Open No. 2021-174858, when the substrate is conveyed by the substrate conveying unit in which the heat generation in the actuator is increased, it is difficult to sufficiently suppress the occurrence of the temperature unevenness in the substrate surface of the substrate.

### SUMMARY

One or more embodiments of the present disclosure are directed to a substrate processing apparatus capable of sufficiently suppressing an occurrence of a temperature unevenness in a substrate surface of a substrate even in a case where the substrate is conveyed at a high speed.

One or more embodiments of a substrate processing apparatus according to the present disclosure may include a stage on which a substrate is mounted, a conveyor that operates to convey the substrate from the stage, a measuring sensor that operates to measure a temperature of the conveyor, an adjuster that operates to adjust a temperature of the substrate mounted on the stage, and a controller or a processor that operates to perform an adjusting step of causing the adjuster to adjust the temperature of the substrate mounted on the stage so as to become the temperature of the conveyor measured by the measuring sensor.

According to other aspects of the present disclosure, one or more additional substrate processing apparatuses, one or more substrate processing methods, and one or more storage mediums are discussed herein. Features of the present disclosure will become apparent from the following description of embodiments with reference to the attached drawings. The following description of embodiments is described by way of example.

### BRIEF DESCRIPTION OF THE DRAWINGS

FIG. 1 is a schematic cross sectional view of at least one embodiment of an exposure apparatus according to one or more aspects of the present disclosure.

FIG. 2 is a schematic top view of at least one embodiment of a conveying mechanism provided in at least one embodiment of an exposure apparatus according to one or more aspects of the present disclosure.

FIG. 3 is a partially enlarged schematic top view of at least one embodiment of an exposure apparatus according to one or more aspects of the present disclosure.

FIG. 4 is a flowchart showing at least one embodiment of a process of adjusting a target temperature of a temperature adjusting plate in at least one embodiment of an exposure apparatus according to one or more aspects of the present disclosure.

FIG. 5A is a view showing an example of a time variation of a temperature of a conveying hand in at least one embodiment of an exposure apparatus according to one or more aspects of the present disclosure.

FIG. 5B is a view showing an example of a time variation of a temperature of a substrate in an exposure apparatus discussed below in the present disclosure.

FIG. 5C is a view showing an example of a time variation of a temperature of a substrate in at least one embodiment of an exposure apparatus according to one or more aspects of the present disclosure.

FIG. 6 is a partially enlarged schematic top view of at least one embodiment of an exposure apparatus according to one or more aspects of the present disclosure.

FIG. 7 is a flowchart showing at least one embodiment of a process of adjusting a target temperature of a temperature adjusting plate in at least one embodiment of an exposure apparatus according to one or more aspects of the present disclosure.

FIG. 8A is a partially enlarged schematic cross sectional view of at least one embodiment of an exposure apparatus according to one or more aspects of the present disclosure.

FIG. 8B is a diagram showing at least one embodiment of a heat resistance circuit that may be used in at least one embodiment of an exposure apparatus according to one or more aspects of the present disclosure.

### DESCRIPTION OF THE EMBODIMENTS

Hereinafter, a substrate processing apparatus according to the present disclosure is described in detail with reference to the accompanying drawings. Note that the drawings described below may be drawn on a scale different from the actual scale in order to facilitate understanding of the present disclosure, and the scale shown does not limit one or more embodiments of the present disclosure.

Further, the embodiments described below do not limit the scope of the present disclosure or any claim(s) in the set of claims.

Furthermore, although a plurality of features are described in the following embodiments, all of the plurality of features are not necessarily essential to one or more of the embodiment of the present disclosure, and the plurality of features may be arbitrarily combined with each other in one or more embodiments.

In addition, hereinafter, a direction parallel to an optical axis of a projecting optical system 7 is defined as a Z direction, and two directions perpendicular to each other in a plane perpendicular to the optical axis are defined as an X direction and a Y direction.

### Configuration(s) of One or More Embodiments

In at least one substrate processing apparatus such as an exposure apparatus or a measurement apparatus used to manufacture a semiconductor device, a substrate is positioned and a temperature of the substrate is adjusted to a predetermined temperature generally before the substrate is conveyed to a substrate stage on which the substrate is processed.

Inventor(s) of the present disclosure have recognized, along with miniaturization and high integration of the semiconductor device, a need to further improve alignment accuracy and overlay accuracy in the semiconductor device, and in particular, a need to have stricter control of the temperature of the substrate.

Specifically, in order to improve the alignment accuracy and the overlay accuracy of the semiconductor device in one or more embodiments, it is preferred or desired to adjust the temperature of the substrate before being conveyed to the substrate stage so as to become uniform in consideration of the temperature of the substrate after being conveyed to the substrate stage.

If a temperature distribution in a substrate surface of the substrate becomes non-uniform, namely in a case where temperature unevenness occurs in the substrate surface, expansion or contraction locally occurs in the substrate, which can change an arrangement and shapes of shot regions in the substrate surface.

In factors that cause the temperature distribution in the substrate surface of the substrate to be non-uniform, a substrate conveying unit or a substrate conveyor for conveying the substrate is included in one or more embodiments.

In one or more embodiments, the substrate conveying unit or substrate conveyor is provided with a plurality of driving shafts for conveying the substrate, and actuators, such as servo motors and linear motors, for driving the plurality of driving shafts are mounted thereon.

In the substrate conveying unit or the substrate conveyor in one or more embodiments, heat is generated in an actuator driven in a case where the substrate is conveyed, and the heat is transmitted to a substrate holding unit (or substrate holder) of the substrate conveying unit or substrate conveyor for holding the substrate, thereby only a region of the substrate which is in contact with the substrate holding unit or holder is increased in temperature. As a result, the temperature distribution in the substrate surface of the substrate becomes non-uniform.

Therefore, in order to suppress the occurrence of the temperature unevenness in the substrate surface of the substrate in a case where the substrate conveying unit or conveyor conveys the substrate, at least one embodiment of a substrate processing apparatus has been proposed which controls a temperature of a region of the substrate which is in contact with the substrate holding unit or holder so as to be lower than the temperature of a region of the substrate which is not in contact with the substrate holding unit or holder.

On the other hand, the heat generation in the actuator has been increased along with an increase in a speed and an acceleration in a case where the substrate is conveyed in the substrate conveying unit or conveyor in a case where a throughput in the substrate processing apparatus has been improved.

Further, in the conventional substrate processing apparatus described in the background above, it is difficult to sufficiently suppress the occurrence of the non-uniformity of the temperature distribution in the substrate surface of the substrate in a case where the substrate is conveyed by the substrate conveying unit in which the heat generation in the actuator is increased.

Accordingly, at least one object of the present disclosure is to provide one or more embodiments of a substrate processing apparatus capable of sufficiently suppressing the occurrence of the non-uniformity of the temperature distribution in the substrate surface of the substrate even in a case where the substrate is conveyed at a high speed.

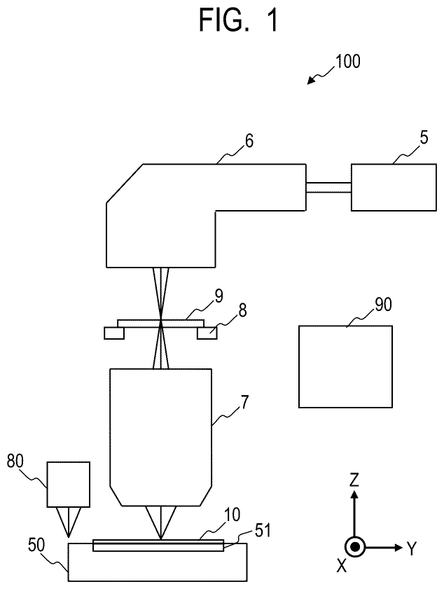

FIG. 1 shows a schematic cross sectional view of at least one embodiment of an exposure apparatus 100 as a substrate processing apparatus according to one or more aspects of the present disclosure.

The exposure apparatus 100 is a lithography apparatus for forming a pattern on a substrate 10, which is used in a lithography process included in processes of manufacturing a device such as a semiconductor element or a liquid crystal display element.

The exposure apparatus 100 includes a light source or light source unit 5, an illuminating optical system 6, a projecting optical system 7, a reticle stage 8, a substrate stage 50, an alignment scope 80, and a controller or processor 90.

The illuminating optical system 6 is configured or operates to shape light from the light source or light source unit 5 into a predetermined shape optimal for exposure and then uniformly illuminate a reticle 9 with the shaped light.

The reticle stage 8 is configured or operates to hold the reticle 9 via a reticle chuck (not shown), and is connected to a reticle driving mechanism (not shown).

The reticle driving mechanism is formed by linear motors or the like, and drives the reticle stage 8 in each of the X direction, the Y direction, the Z direction and rotational directions around the X axis, the Y axis and the Z axis.

Thereby, the reticle 9 held on the reticle stage 8 may be moved to a target position.

The reticle 9 used in the exposure apparatus 100 is made of, for example, quartz, and a pattern (circuit pattern) to be transferred onto a substrate 10 is formed thereon.

A position of the reticle stage 8 is detected by, for example, laser interferometers in six axes (not shown) to be controlled by the controller or processor 90.

The projecting optical system 7 has a function of imaging light from an object plane on an image plane and, specifically, guides the light (diffracted light) that has passed through a pattern formed on the reticle 9 onto the substrate 10 to project an image of the pattern onto a substrate surface of the substrate 10 coated with a photosensitive agent.

The substrate stage 50 is configured or operates to hold the substrate 10 via a substrate chuck 51, and is connected to a substrate driving mechanism (not shown).

The substrate chuck 51 is set to a predetermined temperature by a mechanism (not shown) which is provided in the substrate stage 50 and through which medium for adjusting temperature such as coolant oil or cooling water flows.

The substrate driving mechanism is formed by linear motors or the like, and drives the substrate stage 50 in each of the X direction, the Y direction, the Z direction and the rotational directions around the X axis, the Y axis and the Z axis.

Thereby, the substrate 10 held on the substrate stage 50 may be moved to a target position.

The substrate 10 used in the exposure apparatus 100 is a processed object to which the pattern formed on the reticle 9 is transferred, and includes, for example, a wafer, a liquid crystal substrate, and other substrates to be processed.

A position of the substrate stage 50 is detected by, for example, laser interferometers in six axes (not shown) to be controlled by the controller or processor 90.

The alignment scope 80 is a measuring unit or component for measuring an alignment mark formed on the substrate 10 held by the substrate stage 50.

Specifically, the alignment scope 80 measures a position of the alignment mark formed on the substrate 10 before an overlay exposure in a case where the overlay exposure is performed on a pattern formed on the substrate 10.

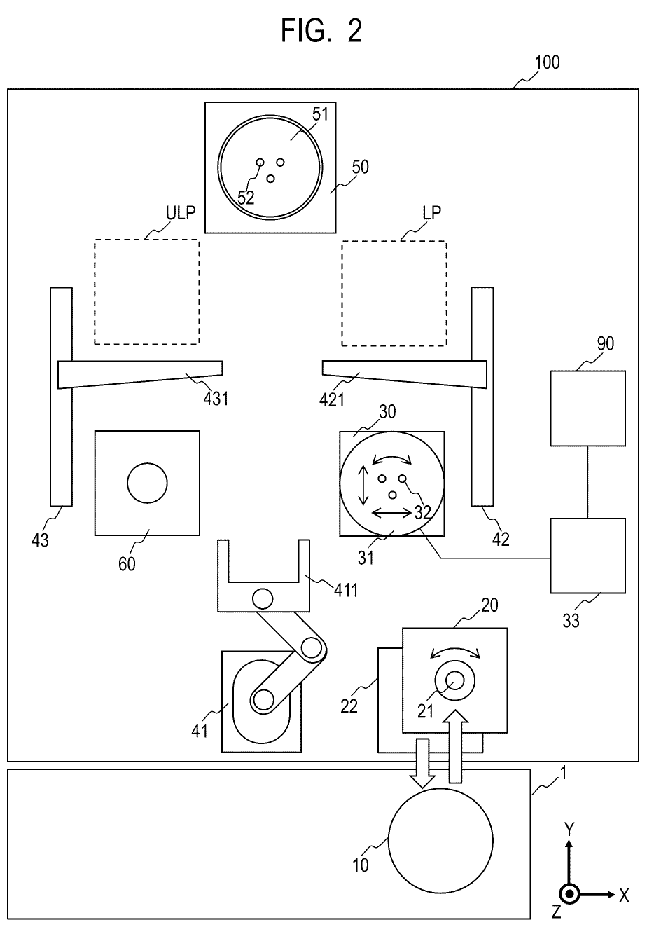

FIG. 2 shows a schematic top view of at least one embodiment of a conveying mechanism that may be provided in the exposure apparatus 100 for loading and unloading the substrate 10.

Specifically, the conveying mechanism includes a first alignment device 20, an unloading table 22, a second alignment temperature adjusting device 30 (stage, adjusting unit), and a temperature adjusting plate controller 33 (controller or processor).

Further, the conveying mechanism includes a first conveying robot 41, a second conveying robot 42 (conveying unit or conveyor), a third conveying robot 43, and a recovering table 60.

The first conveying robot 41, the second conveying robot 42, and the third conveying robot 43 are configured or operate to suck to hold the substrate 10 by a sucking unit or suction component/mechanism (not shown) provided in conveying hands 411, 421, and 431 to convey the substrate 10, respectively.

At this time, heat is generated in a case where actuators (not shown) provided inside the first conveying robot 41, the second conveying robot 42, and the third conveying robot 43 are driven.

Therefore, for example, a root portion of each of the conveying hands 411, 421, and 431 may be formed by a member having low thermal conductivity.

Thereby, it is possible to suppress the heat generated in the first conveying robot 41, the second conveying robot 42, and the third conveying robot 43 from being transferred to the conveying hands 411, 421, and 431, respectively.

Therefore, a temperature uniformity of each of the conveying hands 411, 421, and 431 may be improved.

As shown in FIG. 2, the exposure apparatus 100 may be connected to or in communication with a coating and developing apparatus 1 which has a function of coating a substrate 10 with a photosensitive agent and a function of developing the substrate 10 subjected to exposure processing.

The exposure apparatus 100, and the coating and developing apparatus 1 are usually connected to each other by in-line connection.

In a case where the substrate 10 is loaded from the coating and developing apparatus 1 into the exposure apparatus 100, first, the substrate 10 is conveyed to the first alignment device 20 which is an interface unit between an inside of the exposure apparatus 100 and the coating and developing apparatus 1.

The first alignment device 20 includes a holding unit or holder 21, and the substrate 10 conveyed to the first alignment device 20 is held by the holding unit or holder 21 and then rotated around the Z axis.

Specifically, the holding unit or holder 21 holds, for example, a central portion of the substrate 10 from below, and the first alignment device 20 aligns the substrate 10 such that a reference position such as a notch or an orientation flat of the substrate 10 faces a predetermined direction, for example.

Here, this alignment is performed such that the notch of the substrate 10 falls within a detection range of the second alignment temperature adjusting device 30 in a case where the substrate 10 is conveyed to the second alignment temperature adjusting device 30 described later.

Next, the substrate 10 aligned in the first alignment device 20 is conveyed to the second alignment temperature adjusting device 30 by the first conveying robot 41.

The second alignment temperature adjusting device 30 includes a shape detecting sensor (not shown) for detecting an outer circumferential shape and notch of the substrate 10, and an alignment stage (not shown) for aligning the mounted substrate 10 in each of the X direction, the Y direction, and the rotation direction around the Z axis.

Further, the second alignment temperature adjusting device 30 includes a temperature adjusting plate 31 for adjusting a temperature of the substrate 10 to a predetermined temperature by coming into contact with a rear surface of the substrate 10 on a mounted surface on which the substrate 10 is mounted, and lift pins 32 for transferring the substrate 10.

As shown in FIG. 2, three lift pins 32 are provided in the second alignment temperature adjusting device 30 of the exposure apparatus 100, but the number of lift pins 32 is not limited to a particular number as long as an object of holding the substrate 10 is achieved.

A temperature control of the substrate 10 by the temperature adjusting plate 31 is performed by a temperature adjusting plate controller or processor 33.

Specifically, first, the controller or processor 90 sends information (command value) of a target temperature of the temperature adjusting plate 31 to the temperature adjusting plate controller or processor 33.

Then, the temperature adjusting plate controller or processor 33 controls a temperature adjusting device such as a Peltier element (not shown) based on the received command value and temperature information acquired by a temperature sensor (not shown) provided in the temperature adjusting plate 31.

Here, since the temperature adjusting device is connected to the temperature adjusting plate 31, the temperature adjusting plate 31 is controlled to the predetermined temperature by the temperature adjusting device.

The temperature adjusting plate 31 is formed by a member having a large heat capacity such that a temperature of the temperature adjusting plate 31 itself does not fluctuate due to a temperature of a surrounding environment or a temperature of the substrate 10 sucked to be held on the temperature adjusting plate 31.

The substrate 10 conveyed to the second alignment temperature adjusting device 30 is received from the first conveying robot 41 by the lift pins 32 in the second alignment temperature adjusting device 30.

Thereafter, the substrate 10 is transferred from the lift pins 32 to the temperature adjusting plate 31 by moving the lift pins 32 in the Z direction to a negative side of the temperature adjusting plate 31 or of the second alignment temperature adjusting device 30.

After the temperature adjusting plate 31 applies suction to hold the substrate 10, the temperature of the substrate 10 is adjusted so as to become the predetermined temperature.

Further, a position of the substrate 10 sucked (or undergoing suction) to be held by the temperature adjusting plate 31 is measured by the shape detecting sensor (not shown).

By driving an alignment stage (not shown) in the second alignment temperature adjusting device 30 such that an output of the shape detecting sensor becomes a predetermined output, an alignment of the substrate 10 in the X direction, the Y direction, and the rotational direction around the Z axis is performed.

Here, the predetermined output of the shape detecting sensor corresponds to a position of the substrate 10 on the temperature adjusting plate 31 at which an alignment mark on the substrate surface of the substrate 10 is within the detection range of the alignment scope 80 in a case where the substrate 10 is conveyed to the substrate stage 50 later.

As described above for one or more embodiments, the temperature adjustment and the alignment of the substrate 10 are performed in parallel, in the second alignment temperature adjusting device 30.

Next, the substrate 10 aligned and temperature-controlled in the second alignment temperature adjusting device 30 is transferred from the temperature adjusting plate 31 to the lift pins 32 by moving the lift pins 32 to a positive side in the Z direction.

Thereafter, the substrate 10 held by the lift pins 32 is transferred to the second conveying robot 42 and then conveyed to a position above a supplying position LP by the second conveying robot 42.

Then, after the substrate stage 50 moves to the supplying position LP, lift pins 52 provided on the substrate stage 50 move to a positive side of the substrate stage or of the substrate chuck 51 in the Z direction so as to protrude from a surface of a substrate chuck 51, thereby receiving the substrate 10 from the second conveying robot 42.

Next, the second conveying robot 42 retreats by moving from the supplying position LP to a negative side or direction in the Y direction.

In addition, the lift pins 52 on the substrate stage 50 operate to move to a negative side of the substrate stage or of the substrate chuck 51 in the Z direction so that the substrate chuck 51 receives the substrate 10 from the lift pins 52 and then sucks or applies suction to hold the substrate 10.

Next, the substrate 10 held by the substrate stage 50 is conveyed to a position directly below the alignment scope 80.

Then, the alignment scope 80 calculates a position (positional deviation) of a shot region arranged on the substrate surface of the substrate 10 by detecting an alignment mark provided on a scribe line on the substrate 10 to measure a position of the alignment mark.

Next, the controller or processor 90 drives the substrate stage 50 based on the positions of the alignment mark in the X direction, the Y direction, the Z direction, and the rotational direction about the Z axis, which are obtained by the alignment scope 80.

The substrate 10 whose positional deviation has been corrected on the substrate stage 50 in this manner is conveyed by the substrate stage 50 to a position below the projecting optical system 7 where an image of a pattern formed on the reticle 9 is projected, and then exposure processing is performed via the projecting optical system 7.

Next, in a case where the exposure process on the substrate 10 is completed, the substrate stage 50 moves to a recovering position ULP.

Then, the third conveying robot 43 recovers the substrate 10 from the substrate stage 50 and then conveys the substrate 10 to the recovering table 60.

Next, the substrate 10 conveyed to the recovering table 60 is recovered by the first conveying robot 41, and then conveyed to the unloading table 22 which is the interface portion between the inside of the exposure apparatus 100 and the coating and developing apparatus 1.

Then, the substrate 10 conveyed to the unloading table 22 is recovered by a substrate conveying robot (not shown) provided in the coating and developing apparatus 1, and then subjected to a developing process.

Next, a method of adjusting the target temperature of the temperature adjusting plate 31 provided in the exposure apparatus 100 according to one or more embodiments is described.

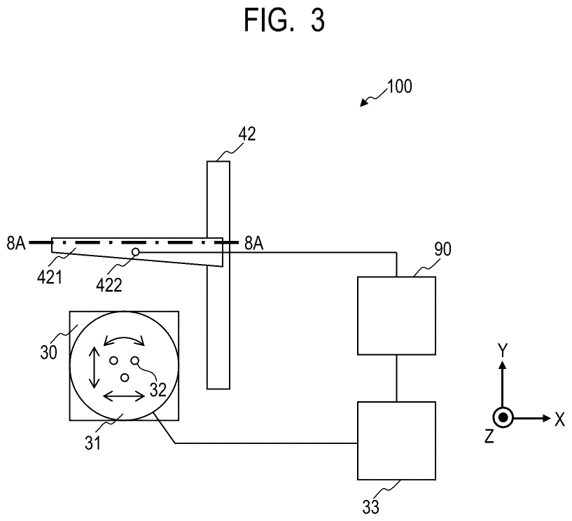

FIG. 3 shows a partially enlarged schematic top view of at least one embodiment of the exposure apparatus 100.

As shown in FIG. 3, a temperature sensor 422 (measuring unit or measurer) is provided at a position close to a substrate holding unit (holding unit or holder) (not shown) of the conveying hand 421 in the exposure apparatus 100 according to one or more embodiments.

Specifically, the temperature sensor 422 is, for example, a contact type temperature sensor such as a temperature measuring resistor body, a thermistor, or a thermocouple.

In the exposure apparatus 100 according to one or more embodiments, a single temperature sensor 422 is provided in the conveying hand 421, but a plurality of temperature sensors 422 may be provided.

Further, as the temperature sensor 422, a non-contact type temperature sensor such as an infrared temperature sensor may be used instead of the contact type temperature sensor.

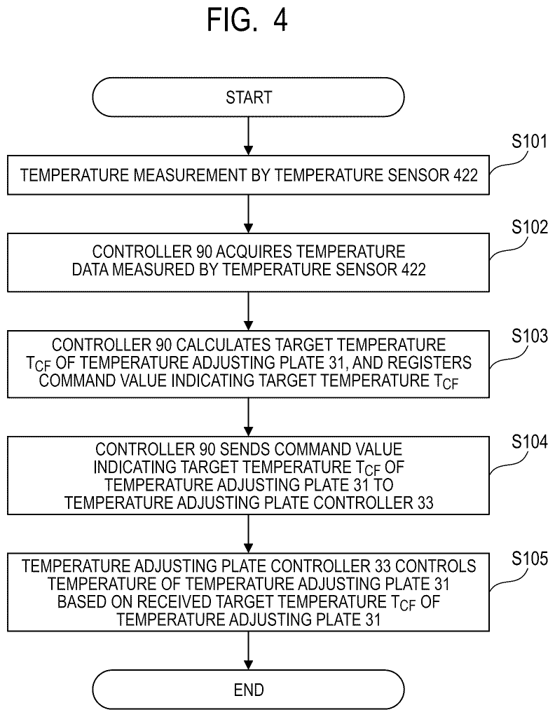

FIG. 4 shows a flowchart of a process of adjusting the target temperature of the temperature adjusting plate 31 in the exposure apparatus 100 according to one or more embodiments.

In a case where the process is started, first, the controller or processor 90 causes the temperature sensor 422 to measure a temperature of a region in the vicinity of the substrate holding unit or holder (not shown) in the conveying hand 421, in other words, the temperature of the vicinity of the region where the conveying hand 421 and the substrate 10 are in contact with each other (Step S101, first measuring step).

Next, the controller or processor 90 acquires the temperature data measured by the temperature sensor 422 in Step S101 (Step S102).

Next, the controller or processor 90 calculates a target temperature T_{CF} of the temperature adjusting plate 31, and registers a command value indicating the calculated target temperature T_{CF} (Step S103).

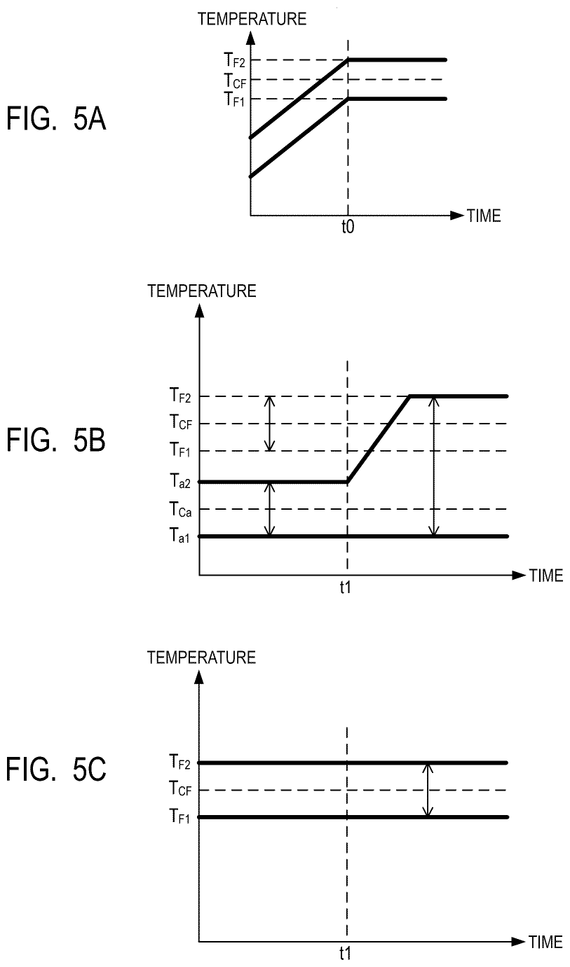

FIG. 5A shows an example of a time variation of the temperature measured by the temperature sensor 422 in the conveying hand 421.

As described above, the conveying hand 421 receives the substrate 10 from the second alignment temperature adjusting device 30 after moving to the position of the second alignment temperature adjusting device 30, or transfers the substrate 10 to the substrate stage 50 after conveying the substrate 10 to the supplying position LP.

Then, it is assumed that the temperature measured by the temperature sensor 422 is stabilized in a temperature range between a temperature T_{F1} and a temperature T_{F2} after a time t0 as shown in FIG. 5A, for example, in a case where the conveying hand 421 performs such driving.

At this time, the exposure apparatus 100 according to one or more embodiments of the present disclosure calculates, as the target temperature T_{CF} of the temperature adjusting plate 31, a central value of the time variation within a predetermined period of the measured temperature between the temperature T_{F1} and the temperature T_{F2} in Step S103.

In Step S103, instead of the central value, an averaged value, a maximum value (namely, the temperature T_{F2}), or a minimum value (namely, the temperature T_{F1}) of the time variation within the predetermined period of the measured temperature between the temperature T_{F1} and the temperature T_{F2} may be calculated as the target temperature T_{CF}.

Next, the controller or processor 90 sends a command value indicating the target temperature T_{CF} of the temperature adjusting plate 31 registered in Step S103 to the temperature adjusting plate controller or processor 33 (Step S104).

Then, the temperature adjusting plate controller or processor 33 controls the temperature of the temperature adjusting plate 31 based on the target temperature T_{CF} of the temperature adjusting plate 31 in the command value received in Step S104 (Step S105, adjusting step), and the process is ended.

In other words, in Step S105, the temperature adjusting plate controller or processor 33 adjusts the temperature of the temperature adjusting plate 31 such that the temperature of the substrate 10 mounted on the second alignment temperature adjusting device 30 becomes the temperature measured by the temperature sensor 422.

FIGS. 5B and 5C show examples of time variation of the temperature of the substrate 10 in a case where the substrate 10 is transferred from the temperature adjusting plate 31 to the conveying hand 421 in an additional exposure apparatus configuration or embodiment and the exposure apparatus 100 according to one or more embodiments of the present disclosure, respectively.

Since the exposure apparatus that may be used to achieve the time variation shown in FIG. 5B may be configured or set up using some of the same or similar structure as that of the exposure apparatus 100 according to one or more embodiments except for at least the temperature adjusting method of the substrate 10 in the temperature adjusting plate 31, a hypothetical discussion is presented using the same members being denoted by the same reference numerals for ease of understanding and highlighting a difference of unevenness versus evenness only, and a description thereof is omitted.

Specifically, in the exposure apparatus that may be used for FIG. 5B, the target temperature of a temperature adjusting plate 31 may be set to the same temperature as a temperature T_{Ca} of an internal space of the exposure apparatus.

Therefore, as shown in FIG. 5B, the temperature of the substrate 10 held by the temperature adjusting plate 31 in a period before a time t1 may be stabilized within a temperature range of a central value T_{Ca}, a minimum value Tₐ₁, and a maximum value Tₐ₂.

That is, a temperature range (temperature unevenness) at each position in the substrate surface of the substrate 10 held by the temperature adjusting plate 31 is Tₐ₂-Tₐ₁.

On the other hand, also in the exposure apparatus that may be used for FIG. 5B, the temperature measured by the temperature sensor 422 in the conveying hand 421 is stabilized in the temperature range of the central value T_{CF}, the minimum value T_{F1}, and the maximum value T_{F2}.

Since the conveying hand 421 is driven variously as described above, the temperature of the temperature adjusting plate 31 is lower than that of the conveying hand 421.

Then, as shown in FIG. 5B, in a case where the substrate 10 is transferred from the temperature adjusting plate 31 to the conveying hand 421 at a time t1, the temperature of the substrate 10 increases from a portion thereof held by the conveying hand 421 in a period after the time t1.

Thereby, the temperature range (temperature unevenness) at each position in the substrate surface of the substrate 10 held by the conveying hand 421 becomes T_{F2}-Tₐ₁, so that it increases.

On the other hand, as described above, the target temperature of the temperature adjusting plate 31 is set to the central value T_{CF} of the time variation of the temperature measured by the temperature sensor 422 in the conveying hand 421 in the exposure apparatus 100 according to one or more embodiments of the present disclosure.

Therefore, as shown in FIG. 5C, the temperature of the substrate 10 held by the temperature adjusting plate 31 in the period before the time t1 is stabilized within the temperature range of the central value T_{CF}, the minimum value T_{F1}, and the maximum value T_{F2}.

That is, the temperature range (temperature unevenness) at each position in the substrate surface of the substrate 10 held by the temperature adjusting plate 31 is T_{F2}-T_{F1}.

Therefore, even in a case where the substrate 10 is transferred from the temperature adjusting plate 31 to the conveying hand 421 at the time t1, the temperature range (temperature unevenness) at each position in the substrate surface of the substrate 10 held by the conveying hand 421 is maintained at T_{F2}-T_{F1} in the period after the time t1.

In other words, in the exposure apparatus 100 according to one or more embodiments of the present disclosure, unlike the exposure apparatus that may be used for FIG. 5B, the temperature width (temperature unevenness) at each position in the substrate surface of the substrate 10 held by the conveying hand 421 does not increase even in a case where the substrate 10 is transferred from the temperature adjusting plate 31 to the conveying hand 421.

In the exposure apparatus 100 according to one or more embodiments, it is preferred that the process of adjusting the target temperature of the temperature adjusting plate 31 shown in FIG. 4 be performed repeatedly at any time, specifically, at a predetermined time intervals, and may be performed, for example, at intervals of several milliseconds or several microseconds.

In the exposure apparatus 100 according to one or more embodiments, the central value T_{CF} itself of the time variation of the temperature measured by the temperature sensor 422 provided in the conveying hand 421 in Step S103 of the process may not be set to the target temperature of the temperature adjusting plate 31.

That is, even while the temperature of the substrate 10 is adjusted to the target temperature T_{CF} by the temperature adjusting plate 31, the temperature of the conveying hand 421 may vary due to the driving thereof.

In this case, the temperature of the substrate 10, in a case where the temperature adjustment is completed in the temperature adjusting plate 31, and the temperature of the conveying hand 421 are different from each other.

Therefore, in Step S103 of the process, the target temperature of the temperature adjusting plate 31 may be calculated in consideration of the temperature variation of the conveying hand 421 while the temperature of the substrate 10 is adjusted to the target temperature in the temperature adjusting plate 31.

As described above, in the exposure apparatus 100 according to one or more embodiments, the temperature of the substrate 10 is adjusted so as to be equal to the temperature of the conveying hand 421 in the temperature adjusting plate 31.

Therefore, in a case where the substrate 10 is held by the conveying hand 421, the deviation between the temperature of the substrate 10 and that of the conveying hand 421 in the region where the substrate 10 and the conveying hand 421 are in contact with each other and in the vicinity thereof is sufficiently reduced.

Accordingly, the substrate 10 may be transferred from the conveying hand 421 of the second conveying robot 42 to the substrate stage 50 while uniformly maintaining the temperature at each position in the substrate surface in one or more embodiments.

That is, the exposure apparatus 100 according to one or more embodiments may perform the temperature adjustment with high accuracy even in a case where the substrate 10 is conveyed at a high speed.

Note that the temperature of the substrate 10 uniformly varies to the temperature of the substrate stage 50 as time elapses such that the measurement of the position of the substrate 10 by the alignment scope 80 and the exposure process of the substrate 10 are performed after the substrate 10 has been held by the substrate stage 50.

At this time, a change in shape of each shot region associated with a variation in the temperature of the substrate 10 may be corrected by magnification correction, so that deteriorations in the overlay accuracy and the alignment accuracy may be sufficiently suppressed.

In addition, the above-described effect may be obtained by providing the temperature sensor 422 in the conveying hand 421 in the exposure apparatus 100 according to one or more embodiments.

Therefore, even in a case where the substrate 10 is conveyed at a high speed by the conveying hand 421, it is possible to sufficiently suppress the deteriorations in the overlay accuracy and the alignment accuracy.

That is, in the exposure apparatus 100 according to one or more embodiments of the present disclosure, even in a case where the conveying hand 421 conveys the substrate 10 at a high speed, high temperature adjustment accuracy of the substrate 10 may be achieved, and the deteriorations in the overlay accuracy and the alignment accuracy may be sufficiently suppressed.

The above-described structure of the exposure apparatus 100 according to one or more embodiments may be applied not only to the conveyance of the substrate 10 but also to a conveyance of the reticle 9.

### Configuration(s) for One or More Additional Embodiments

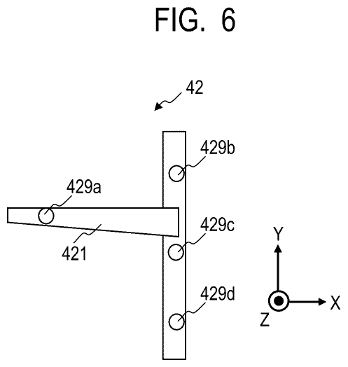

FIG. 6 shows a partially enlarged schematic top view of at least one embodiment of an exposure apparatus according to one or more additional embodiments of the present disclosure.

The exposure apparatus according to one or more additional embodiments has the same structure as that of the exposure apparatus 100 according to one or more of the aforementioned embodiments except that the second conveying robot 42 is provided with temperature sensors 429a to 429d (measuring unit or measurer) instead of the temperature sensor 422. For example, a plurality of sensors may be used instead of one sensor, or the sensor may include a plurality of sensors. Therefore, the same members are denoted by the same reference numerals, and description thereof is omitted.

In the exposure apparatus 100 according to one or more of the aforementioned embodiments, it may be difficult to provide the temperature sensor 422 at a position close to the substrate holding unit or holder of the conveying hand 421 of the second conveying robot 42 in a case where a clearance between the second conveying robot 42 and the surrounding units or components is narrow.

Therefore, in the exposure apparatus according to one or more additional embodiments, first, the temperature sensor 429a may be provided at the position close to the substrate holding unit of the conveying hand 421, and the temperature sensors 429b to 429d may be provided at portions other than the conveying hand 421 of the second conveying robot 42, as shown in FIG. 6.

In other words, in the exposure apparatus according to one or more additional embodiments, the temperature sensors 429b to 429d may be provided at three portions of a driving unit (or driver) of the second conveying robot 42.

Then, a correlation between a temperature measured by the temperature sensor 429a and a temperature measured by each of the temperature sensors 429b to 429d may be obtained in advance.

Specifically, for example, it is assumed that temperatures T1, T2, T3, and T4 are measured by the temperature sensors 429a to 429d, respectively, at a time (timing, first time) in a case where the conveyance of the substrate 10 is started.

Further, it is assumed that temperatures T5, T6, T7, and T8 are measured by the temperature sensors 429a to 429d, respectively, at a predetermined time (timing, second time) in a transient state in the conveyance of the substrate 10.

Furthermore, it is assumed that temperatures T9, T10, T11, and T12 are measured by the temperature sensors 429a to 429d, respectively, at a predetermined time (timing, third time) in a stationary state in the conveyance of the substrate 10.

Then, a temperature table indicating a relationship among the temperature sensors 429a to 429d as shown in the following Table 1 may be created and obtained from the measurement result in the above-described measuring process (second measuring step).

TABLE 1

| | Temperature when | | |
|---|---|---|---|
| Temperature | conveyance of | Temperature in | Temperature in |
| sensors | substrate is started | transient state | stationary state |
| 429a | T1 | T5 | T9 |
| 429b | T2 | T6 | T10 |
| 429c | T3 | T7 | T11 |
| 429d | T4 | T8 | T12 |

That is, in the exposure apparatus according to one or more embodiments, the temperature sensor 429a arranged at a position close to the substrate holding unit or holder of the conveying hand 421 of the second conveying robot 42 may be removed in a case where the exposure process is performed on the substrate 10.

A temperature at the position close to the substrate holding unit or holder may be obtained by referring to the temperature table obtained as described above based on temperatures measured by the temperature sensors 429b to 429d.

Note that the temperature measurements by the temperature sensors 429a to 429d in a case where the temperature table is obtained is not limited to the above-described three times, and may be performed at least one time, preferably a plurality of times.

In addition, as the temperature sensors arranged in the portions other than the conveying hand 421 of the second conveying robot 42, the temperature sensors 429b to 429d may be provided in the exposure apparatus according to one or more embodiments, but at least one temperature sensor may be provided (and such sensors are not limited to three only).

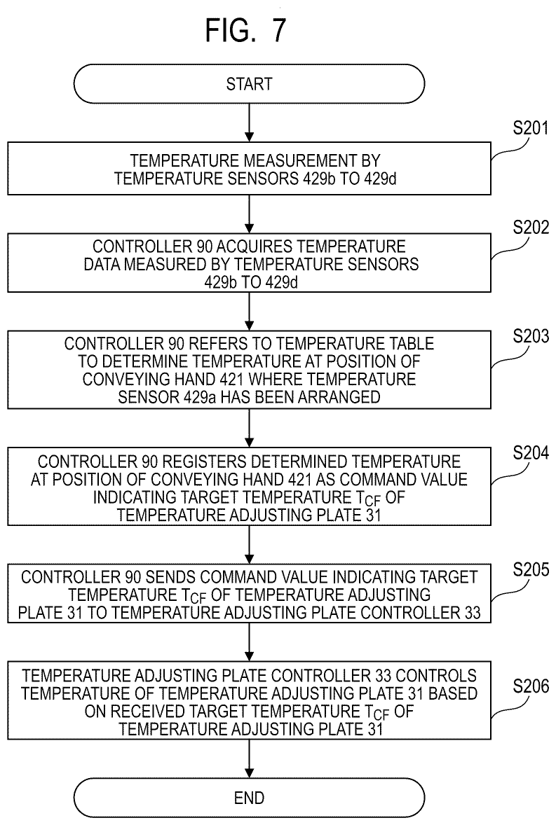

FIG. 7 shows a flowchart of at least one embodiment of a process of adjusting the target temperature of the temperature adjusting plate 31 in the exposure apparatus according to one or more additional embodiments of the present disclosure.

In a case where the process is started, first, the controller or processor 90 causes each of the temperature sensors 429b to 429d arranged at the portions other than the conveying hand 421 of the second conveying robot 42 to measure the temperature (Step S201).

Next, the controller or processor 90 obtains the temperatures of the portions where the temperature sensors 429b to 429d are arranged in the second conveying robot 42 obtained in Step S201 (Step S202).

Then, the controller or processor 90 refers to the temperature table based on the obtained temperatures measured by the temperature sensors 429b to 429d to determine the temperature at the position of the conveying hand 421 where the temperature sensor 429a has been arranged (Step S203, first determining step).

That is, in Step S203, the temperature at the position of the conveying hand 421 corresponding to the temperatures measured by the temperature sensors 429b to 429d in Step S202 is determined.

Specifically, for example, the temperature at the position of the conveying hand 421 is determined as T1 from the temperature table in a case where the temperatures measured by the temperature sensors 429b to 429d are T2, T3, and T4, respectively.

Next, the controller or processor 90 registers the temperature obtained in Step S203 as a command value indicating the target temperature T_{CF} of the temperature adjusting plate 31 (Step S204).

Then, the controller or processor 90 sends the command value indicating the target temperature T_{CF} of the temperature adjusting plate 31 registered in Step S204 to the temperature adjusting plate controller or processor 33 (Step S205).

Finally, the temperature adjusting plate controller or processor 33 controls the temperature of the temperature adjusting plate 31 based on the target temperature T_{CF} of the temperature adjusting plate 31 in the command value received in Step S205 (Step S206), and the process is ended.

As described above, in the exposure apparatus according to one or more additional embodiments, the temperature of the substrate 10 is adjusted on the temperature adjusting plate 31 so as to be equal to the temperature at the position where the temperature sensor 429a of the substrate holding unit of the conveying hand 421 has been arranged.

Therefore, in a case where the substrate 10 is held by the conveying hand 421, a deviation between the temperature of the substrate 10 and that of the conveying hand 421 in a region where the substrate 10 and the conveying hand 421 are in contact with each other and in the vicinity thereof is sufficiently reduced.

That is, in the exposure apparatus according to one or more additional embodiments, even in a case where it is difficult to arrange the temperature sensor 429a at a position in the vicinity of the substrate holding unit or holder of the conveying hand 421 such that the temperature at the position may not be directly measured, the temperature at the position may be determined.

In other words, in the exposure apparatus according to one or more additional embodiments, the temperature table indicating the correlation between the temperature of the position in the vicinity of the substrate holding unit of the conveying hand 421 in the second conveying robot 42 and the temperatures of the portions other than the position is obtained in advance.

Then, it is possible to determine the target temperature of the temperature adjusting plate 31 by estimating the temperature of the position by referring to the temperature table based on the measured temperatures of the portions other than the position.

### Configuration(s) for One or More Further Embodiments

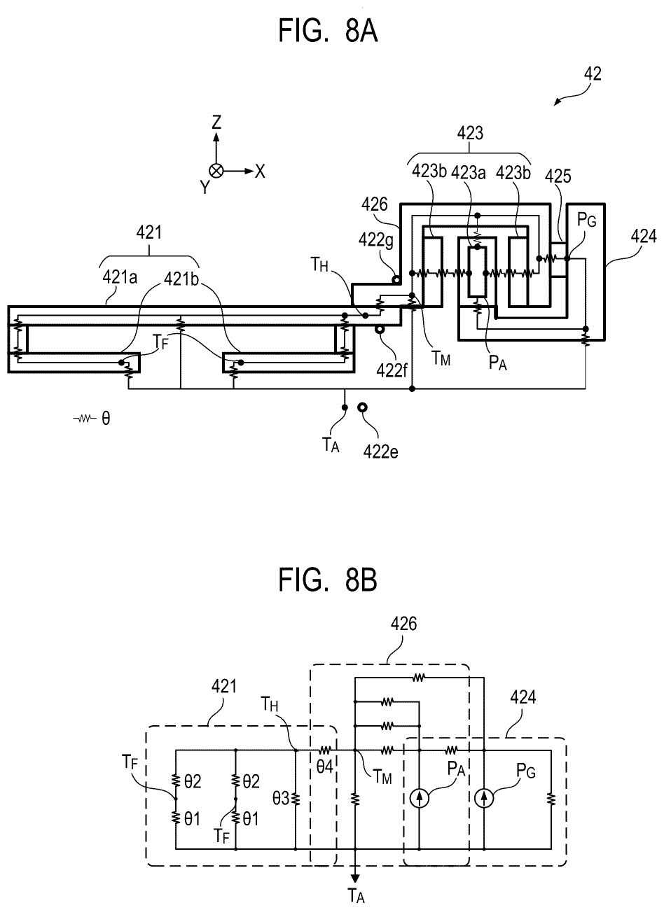

FIG. 8A shows a partially enlarged schematic cross sectional view taken along a line 8A-8A shown in FIG. 3 in the exposure apparatus according to one or more further embodiments of the present disclosure.

The exposure apparatus according to one or more further embodiments has the same structure as that of the exposure apparatus 100 according to one or more of the aforementioned embodiments except that the second conveying robot 42 is provided with temperature sensors 422e to 422g (measuring unit or measurer) instead of the temperature sensor 422 (for example, a plurality of sensors may be used). Therefore, the same members are denoted by the same reference numerals, and description thereof is omitted.

FIG. 8A also shows a heat resistance model of the second conveying robot 42 provided in the exposure apparatus according to one or more further embodiments.

Specifically, heat sources of the second conveying robot 42 include an actuator 423 for driving the conveying hand 421 in the Y direction and a guide 425 for moving the conveying hand 421 along the Y direction.

Further, for example, a linear motor may be used as the actuator 423, and electrical power is generated to generate heat P_{A} in a case where an electrical current flows through a coil 423a in the linear motor.

Furthermore, for example, a linear guide using a ball bearing may be used as the guide 425, and heat PG is generated by friction due to mutual sliding of the ball bearing and a rail in the linear guide.

Then, the heat P_{A} generated in the actuator 423 and the heat PG generated in the guide 425 flow to each component forming the second conveying robot 42 according to conduction, radiation, and convection, and are then radiated to the surrounding environment.

The components forming the second conveying robot 42 include a hand base 421a of the conveying hand 421, fingers 421b of the conveying hand 421, the coil 423a of the actuator 423, and magnets 423b of the actuator 423, for example.

Further, the components forming the second conveying robot 42 include a base 424 (stator), the guide 425 (stator), and a movable element 426, for example.

In the second conveying robot 42, the hand base 421a is coupled to each of the fingers 421b, and a driving unit formed by the actuator 423, the base 424, the guide 425, and the movable element 426.

Then, in the second conveying robot 42, heat resistances θ are formed on joint surfaces between the respective components, and between each component and the surrounding environment, and the heat flows through the heat resistances θ, as shown in FIG. 8A.

Here, as shown in FIG. 8A, it is assumed that a temperature of the surrounding environment is represented by T_{A}, a temperature of the movable element 426 is represented by T_{M}, a temperature of the hand base 421a of the conveying hand 421 is represented by T_{H}, and a temperature of the fingers 421b of the conveying hand 421 is represented by T_{F}.

At this time, the heat resistance model shown in FIG. 8A in the second conveying robot 42 may be expressed as a heat resistance circuit as shown in FIG. 8B.

The heat resistance circuit including the heat resistances θ, the temperatures T, and the heat sources P as shown in FIG. 8B may be replaced with an electrical circuit including electrical resistances R, electrical voltages V, and electrical currents I.

That is, the heat resistances θ, the temperatures T, and the heat sources P correspond to the electrical resistances R, the electrical voltages V, and the electrical currents I between the heat resistance circuit and the electrical circuit, respectively.

Then, the temperature T_{F} of the fingers 421b may be calculated as expressed by the following Expression (1) from the heat resistances θ₁ and θ₂ between the conveying hand 421 and the surrounding environment, the temperature T_{A} of the surrounding environment, and the temperature T_{H} of the hand base 421a (second determining step):

$${T}_{F} = {T}_{H} - \frac{{θ}_{2}}{{θ}_{1} + {θ}_{2}} \times ( {T}_{H} - {T}_{A} ) . \qquad ( 1 )$$

That is, the temperature T_{F} of the fingers 421b may be calculated from a voltage division calculation in the electrical circuit corresponding to the heat resistance model in the conveying hand 421 of the second conveying robot 42.

Thereby, the heat resistances θ₁ and θ₂ are known, and the temperature T_{A} of the surrounding environment and the temperature T_{H} of the hand base 421a are measured by the temperature sensors 422e and 422f, respectively, thereby the temperature T_{F} of the fingers 421b may be calculated from Expression (1).

Then, as in the exposure apparatus 100 according to one or more aforementioned embodiments, the calculated temperature T_{F} of the fingers 421b is registered as a command value indicating the target temperature T_{CF} of the temperature adjusting plate 31, and the temperature adjusting plate controller or processor 33 controls the temperature of the temperature adjusting plate 31 based on the command value.

On the other hand, the temperature T_{F} of the fingers 421b may also be obtained by calculating the heat P_{H} flowing through the hand base 421a from the temperature T_{M} of the movable element 426, the temperature T_{H} of the hand base 421a, and the heat resistance θ₄ between the movable element 426 and the hand base 421a.

Specifically, the heat P_{H} flowing through the hand base 421a may be expressed by the following Expression (2):

$${P}_{H} = \frac{{T}_{M} - {T}_{H}}{{θ}_{4}} . \qquad ( 2 )$$

Next, in a case where a combined heat resistance of the heat resistances θ1, θ2, and θ3 in a region of the conveying hand 421 is represented by θ₀, the heat P_{F} flowing in the fingers 421b may be expressed by the following Expression (3) from a current division calculation in the electrical circuit:

$${P}_{F} = \frac{{θ}_{0}}{{θ}_{1} + {θ}_{2}} \times {P}_{H} . \qquad ( 3 )$$

Further, the temperature T_{F} of the fingers 421b may be expressed by the following Expression (4) based on Ohm's law in the electrical circuit:

$${T}_{F} = {T}_{H} - {θ}_{2} \times {P}_{F} . \qquad ( 4 )$$

That is, the temperature T_{F} of the fingers 421b may be expressed as the following Expression (5) by substituting Expressions (2) and 3 into Expression (4):

$${T}_{F} = {T}_{H} - {θ}_{2} \times \frac{{θ}_{0}}{{θ}_{1} + {θ}_{2}} \times \frac{{T}_{M} - {T}_{H}}{{θ}_{4}} . \qquad ( 5 )$$

Therefore, in a case where the heat resistances θ₁, θ₂, θ₃, and θ₄ are known, and the temperature T_{M} of the movable element 426 and the temperature T_{H} of the hand base 421a are measured by the temperature sensors 422g and 422f, respectively, the temperature T_{F} of the fingers 421b may be calculated from Expression (5) (determining step).

Although omitted in the above-described discussion, since each component forming the second conveying robot 42 also has a heat capacity, the temperatures gradually rise in accordance with a predetermined time constant in a case where the heat flows.

In this case, the heat capacity may be represented as a capacitance C in the heat resistance circuit, so that the heat resistance model in the second conveying robot 42 may be more strictly formed by adding the capacitance C to the heat resistance circuit.

As described above, in the exposure apparatus according to one or more further embodiments, the temperature of the substrate 10 may be adjusted on the temperature adjusting plate 31 so as to become equal to the temperature at the position of the substrate holding unit or holder of the conveying hand 421.

That is, in the exposure apparatus according to one or more further embodiments, the controller or processor 90 may calculate the temperature T_{F} of the fingers 421b, and the temperature adjusting plate controller or processor 33 may control the temperature of the temperature adjusting plate 31 so as to become the calculated temperature T_{F}.

In other words, in the exposure apparatus according to one or more further embodiments, the temperature T_{F} of the fingers 421b may be calculated by inputting the temperature T_{A} of the surrounding environment, the temperature T_{M} of the movable element 426, and the temperature T_{H} of the hand base 421a of the conveying hand 421 to the heat resistance model instead of measuring the temperature T_{F} of the fingers 421b using a temperature sensor.

Therefore, in a case where the substrate 10 is held by the conveying hand 421, the deviation between the temperature of the substrate 10 and that of the conveying hand 421 in the region where the substrate 10 and the conveying hand 421 are in contact with each other and in the vicinity thereof is sufficiently reduced.

According to the present disclosure, it is possible to provide at least one embodiment of a substrate processing apparatus capable of sufficiently suppressing the occurrence of temperature unevenness in the substrate surface of the substrate even in a case where the substrate is conveyed at a high speed.

The structure of the conveying mechanism for the substrate 10 in the exposure apparatus has been described above, but the scope of the present disclosure is not limited to this.

That is, the above-described structure may also be applied to a lithography apparatus other than the exposure apparatus, such as an imprint apparatus or a charged particle beam drawing apparatus, a measurement apparatus such as a pre-alignment measurement apparatus, and an inspection apparatus such as an overlay inspection apparatus, for example.

Further, although the substrate processing apparatus according to one or more embodiments has been described above, one or more embodiments of a substrate processing method and one or more embodiments of a non-transitory storage medium having a program for causing a computer to execute the substrate processing method described above are also included in the scope of the present disclosure.

Furthermore, a computer-readable recording medium, such as a non-transitory computer-readable recording medium or storage medium, in which the program for causing a computer to execute the substrate processing method described above is recorded or stored is also included in the scope of the present disclosure.

### One or more Embodiments of a Method for Manufacturing Article

At least one embodiment of a method for manufacturing an article according to the present disclosure is suitable for manufacturing an article including a device such as a semiconductor element, a magnetic storage medium, or a liquid crystal display element.

Specifically, at least one method for manufacturing an article according to the present disclosure includes a step of exposing the substrate 10 such that a pattern is formed on the substrate surface of the substrate 10 coated with a photosensitive agent by using the exposure apparatus as the substrate processing apparatus according to any one of the aforementioned embodiments of the present disclosure.

Further, the at least one method for manufacturing an article according to the present disclosure includes a step of developing (processing) the exposed substrate 10.

Note that one or more methods of the present disclosure using the exposure apparatus may include a step of exposing the substrate 10 using information about an arrangement and shapes of a plurality of shot regions on the substrate 10 measured by a predetermined measuring apparatus.

The at least one method for manufacturing an article according to the present disclosure may also include other known steps such as oxidation, film formation, vapor deposition, doping, planarization, etching, photosensitive agent peeling, dicing, bonding, and packaging.

The at least one method for manufacturing an article according to the present disclosure may manufacture a high-quality article as compared with the related art discussed above in the background section.

Note that one or more embodiments of a method of manufacturing an article according to the present disclosure may be performed by using not only the exposure apparatus but also a lithography apparatus such as an imprint apparatus or drawing apparatus.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims priority to and the benefit of Japanese Patent Application No. 2024-167514, filed Sep. 26, 2024, which is hereby incorporated by reference herein in its entirety.

What is claimed is:

1. A substrate processing apparatus, comprising:
a stage on which a substrate is mounted;
a conveyor that operates to convey the substrate from the stage;
a measuring sensor that operates to measure a temperature of the conveyor;
an adjuster that operates to adjust a temperature of the substrate mounted on the stage; and
a controller that operates to perform an adjusting step of causing the adjuster to adjust the temperature of the substrate mounted on the stage so as to become the temperature of the conveyor measured by the measuring sensor.

2. The substrate processing apparatus according to claim 1,
wherein the conveyor includes a holder that operates to hold the substrate, and a driver that operates to move the holder,
wherein the measuring sensor operates to measure a temperature of the holder, and
wherein the adjusting step includes:
a first measuring step of causing the measuring sensor to measure the temperature of the holder; and
a step of causing the adjuster to adjust the temperature of the substrate mounted on the stage so as to become the temperature of the holder measured in the first measuring step.

3. The substrate processing apparatus according to claim 1, wherein the adjusting step includes a step of determining a central value of a time variation of the temperature of the conveyor measured by the measuring sensor within a predetermined period as the temperature of the conveyor.

4. The substrate processing apparatus according to claim 1,
wherein the conveyor includes a holder that operates to hold the substrate, and a driver that operates to move the holder,
wherein the measuring sensor operates to measure a temperature of at least one portion of the driver, and
wherein the adjusting step includes:
a first determining step of determining the temperature of the holder corresponding to the temperature of the at least one portion of the driver measured by the measuring sensor from a table indicating a relationship between the temperature of the at least one portion of the driver and the temperature of the holder; and
a step of causing the adjuster to adjust the temperature of the substrate mounted on the stage so as to become the temperature of the holder determined in the first determining step.

5. The substrate processing apparatus according to claim 4, wherein the adjusting step includes a step of causing the measuring sensor to measure the temperature of the at least one portion of the driver.

6. The substrate processing apparatus according to claim 4, wherein the controller further operates to perform:
a second measuring step of measuring the temperature of the holder and the temperature of the at least one portion of the driver at each of a plurality of times including a first time in a case where a conveyance of the substrate is started, a second time in a transient state in the conveyance of the substrate, and a third time in a stationary state in the conveyance of the substrate; and
a step of creating the table from the temperature of the holder and the temperature of the at least one portion of the driver at each of the plurality of times measured in the second measuring step.

7. The substrate processing apparatus according to claim 1,
wherein the conveyor includes a holder that operates to hold the substrate, and a driver that operates to move the holder,
wherein the holder includes a finger that operates to hold the substrate, and a hand base coupled to each of the finger and the driver,
wherein the measuring sensor operates to measure a temperature of the hand base, and
wherein the adjusting step includes:
a second determining step of determining a temperature of the finger based on the temperature of the hand base measured by the measuring sensor in a heat resistance model of the conveyor; and
a step of causing the adjuster to adjust the temperature of the substrate mounted on the stage so as to become the temperature of the finger determined in the second determining step.

8. The substrate processing apparatus according to claim 7, wherein the adjusting step includes a step of causing the measuring sensor to measure the temperature of the hand base.

9. The substrate processing apparatus according to claim 7,
wherein the measuring sensor further operates to measure a temperature of a region surrounding the conveyor, and
wherein the second determining step includes a step of determining the temperature of the finger from the temperature of the hand base and the temperature of the region measured by the measuring sensor in the heat resistance model of the conveyor.

10. The substrate processing apparatus according to claim 7, wherein the controller further operates to perform a step of creating a heat resistance model of the holder as the heat resistance model of the conveyor.

11. The substrate processing apparatus according to claim 1, wherein the controller operates to perform the adjusting step every time a predetermined time elapses.

12. The substrate processing apparatus according to claim 1, wherein the stage is an alignment stage on which an alignment of the substrate is performed.

13. The substrate processing apparatus according to claim 1, further comprising a substrate stage on which the substrate is processed,
wherein the conveyor operates to convey the substrate from the stage to the substrate stage.

14. The substrate processing apparatus according to claim 1, wherein the measuring sensor includes at least one temperature sensor each of which operates to measure the temperature of the conveyor by coming into contact with the conveyor.

15. The substrate processing apparatus according to claim 1, wherein the measuring sensor includes at least one temperature sensor each of which operates to measure the temperature of the conveyor without contacting the conveyor.

16. The substrate processing apparatus according to claim 1, wherein the adjuster includes a temperature adjusting plate which comes into contact with a rear surface of the substrate on a mounted surface of the stage on which the substrate is mounted.

17. The substrate processing apparatus according to claim 1,
wherein the conveyor includes a holder that operates to hold the substrate, and a driver that operates to move the holder, and
wherein the driver includes a linear motor formed by a movable element and a stator.

18. The substrate processing apparatus according to claim 1, wherein the substrate processing apparatus is an exposure apparatus, an imprint apparatus, a charged particle beam drawing apparatus, a pre-alignment measurement apparatus, or an overlay inspection apparatus.

19. A method for manufacturing an article, the method comprising:
a step of processing a substrate by using the substrate processing apparatus according to claim 1; and
a step of manufacturing the article from the processed substrate.

20. A substrate processing method for processing a substrate in a substrate processing apparatus including a stage on which the substrate is mounted, a conveyor that operates to convey the substrate from the stage, a measuring sensor that operates to measure a temperature of the conveyor, and an adjuster that operates to adjust a temperature of the substrate mounted on the stage, the substrate processing method comprising:
an adjusting step of causing the adjuster to adjust the temperature of the substrate mounted on the stage so as to become the temperature of the conveyor measured by the measuring sensor.

21. A non-transitory computer-readable recording medium recording a program which, when executed by a computer, causes the computer to execute a substrate processing method, the substrate processing method comprising:
an adjusting step of causing an adjuster to adjust a temperature of a substrate mounted on a stage so as to become a temperature of a conveyor measured by a measuring sensor in a substrate processing apparatus including the stage on which the substrate is mounted, the conveyor operating to convey the substrate from the stage, the measuring sensor operating to measure the temperature of the conveyor, and the adjuster operating to adjust the temperature of the substrate mounted on the stage.
